(19) United States
(12) Patent Application Publication
(10) Pub. No.: US 2013/0320969 A1
(43) Pub. Date: Dec. 5, 2013

(54) MAGNETIC FIELD SENSOR

(71) Applicants: Frank REICHENBACH, Wannweil (DE); Paul FARBER, Budapest (DE); Frederic Njikam NJIMONZIE, Reutlingen (DE); Frank SCHATZ, Kornwestheim (DE); Christian PATAK, Reutlingen (DE); Stefan WEISS, Tuebingen (DE); Joerg MARKTANNER, Reutlingen (DE)

(72) Inventors: Frank REICHENBACH, Wannweil (DE); Paul FARBER, Budapest (DE); Frederic Njikam NJIMONZIE, Reutlingen (DE); Frank SCHATZ, Kornwestheim (DE); Christian PATAK, Reutlingen (DE); Stefan WEISS, Tuebingen (DE); Joerg MARKTANNER, Reutlingen (DE)

(73) Assignee: ROBERT BOSCH GMBH, Stuttgart (DE)

(21) Appl. No.: 13/907,138

(22) Filed: May 31, 2013

(30) Foreign Application Priority Data
May 31, 2012 (DE) 102012209232.3

(51) Int. Cl. G01R 33/02; G01R 33/00

(52) U.S. Cl. CPC G01R 33/02; G01R 33/0052
USPC 324/247; 427/128; 427/596

(57) ABSTRACT

A magnetic field sensor having a first magnetic sensor core for measuring a magnetic field in a first measuring direction, and a second magnetic sensor core for measuring a magnetic field in a second measuring direction, the first and second magnetic sensor cores having a shared magnetic anisotropy.

### CROSS REFERENCE

The present application claims the benefit under 35 U.S.C. §119 of German Patent Application No. DE 102012209232.3 filed on May 31, 2012, which is expressly incorporated herein by reference in its entirety.

### FIELD

The present invention relates to a magnetic field sensor.

### BACKGROUND INFORMATION

A device for measuring the direction and/or strength of a magnetic field is described in German Patent Application No. DE 10 2008 042 800 A1. The device is situated on a substrate. A Hall sensor is situated on the surface of the substrate, which is provided for the purpose of detecting a magnetic field component Z, which acts substantially perpendicularly to the surface of the substrate. Furthermore, two flux gate sensors are provided, in order to detect a magnetic field component in the X-Y plane of the substrate. Therefore, together with the Hall sensor, three components may be determined in all three spatial directions.

### SUMMARY

The present invention provides a magnetic field sensor, an array, a component, and a method.

In accordance with the present invention, an example magnetic field sensor is provided having a first magnetic sensor core for measuring a magnetic field in a first measuring direction, and a second magnetic sensor core for measuring a magnetic field in a second measuring direction, the first and second magnetic sensor cores having a shared magnetic anisotropy.

Furthermore, the present invention provides an example method for manufacturing a magnetic field sensor having the following steps: applying a first magnetic sensor core to a substrate having an anisotropy at a predetermined angle to a measuring direction of the sensor core, and applying a second magnetic sensor core to the substrate having an anisotropy at a predetermined angle to a measuring direction of the sensor core, the angle of the anisotropy to the measuring direction of the particular sensor core being selected in such a way that the first and second magnetic sensor cores have a shared anisotropy.

In accordance with the present invention, the magnetic sensor cores are provided with an anisotropy which allows improved sudden magnetic reversal. This is achieved in that the magnetic sensor cores have a shared anisotropy, preferably of 45° to their measuring direction. Thus, on the one hand, magnetic reversal of the core center to the outside occurs and, on the other hand, the magnetic anisotropy may be formed in a structuring step, for example, without the substrate having to be repositioned or rotated for the magnetic anisotropy of the particular magnetic sensor core.

In one specific embodiment of the present invention, the angle of the magnetic anisotropy of the first magnetic sensor core to its measuring direction and the angle of the magnetic anisotropy of the second magnetic sensor core to its measuring direction are each 45°. The magnetic anisotropy may be formed simultaneously on the substrate or in one step for both magnetic sensor cores, which results in shortening and simplification of the manufacture and furthermore in reduced manufacturing costs.

In another specific embodiment according to the present invention, the particular magnetic sensor core may have at least one coil for determining a magnetic reversal of the magnetic sensor core. A periodic voltage may be applied to the coil, for example, in particular a delta voltage. The provision of only one coil has the advantage that, on the one hand, magnetic reversal of the magnetic sensor core is also possible using only one coil and, on the other hand, manufacturing costs may thus be reduced.

In another specific embodiment according to the present invention, the magnetic field sensor may additionally have a third magnetic sensor core for measuring a magnetic field in a third measuring direction. The magnetic field may thus be determined in all spatial directions. Instead of a third magnetic sensor core, a Hall sensor may be provided in this case, which may measure in a Z direction perpendicular to the substrate, for example.

In one specific embodiment of the present invention, an array made of multiple magnetic field sensors is provided. The magnetic field sensors measure at least two spatial directions, for example, an X-Y plane. Parts may be examined for flaws with the aid of such an array, for example, cast parts for bubbles, cracks, etc.

Furthermore, in another specific embodiment of the present invention, the magnetic field sensor may be used to determine a magnetic field or at least one component of a magnetic field in a component, for example, a mobile telephone, a PC, a tablet PC, a notebook, and/or a navigation device.

### BRIEF DESCRIPTION OF THE DRAWINGS

Further features and advantages of the present invention are described in greater detail below on the basis of the figures.

FIG. 1 shows a schematic diagram of one specific embodiment of a magnetic field sensor according to the present invention.

FIG. 2 shows an array made of multiple magnetic field sensors according to FIG. 1.

FIG. 3 shows an exemplary embodiment of a flow chart for the manufacture of a magnetic field sensor according to FIG. 1.

### DETAILED DESCRIPTION OF EXAMPLE EMBODIMENTS

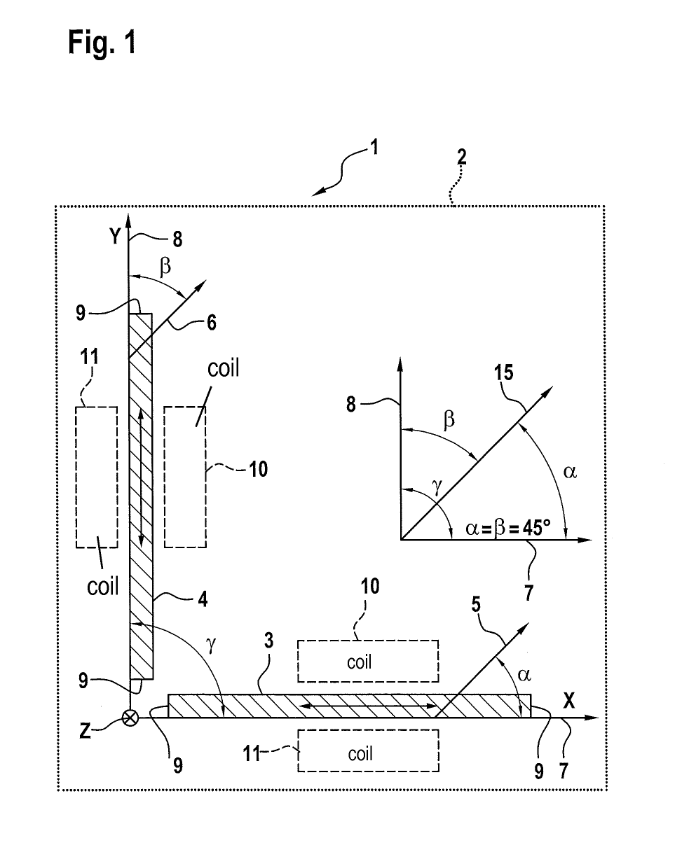

FIG. 1 shows a schematic diagram of a magnetic field sensor 1 according to one specific embodiment of the present invention. Magnetic field sensor 1 is shown in a top view.

A so-called flux gate is a conventional technology for detecting the Earth's magnetic field or for measuring relatively weak magnetic fields. There are various specific embodiments in this case. One particularly simple specific embodiment includes only two coils and a ferromagnetic core. The first coil is operated using a delta current. If a specific field strength in the core is exceeded, its magnetism is reversed and generates a voltage pulse in the second core. The field strength to be measured may be inferred from the occurrence with respect to time of the voltage pulse in relation to the delta current. Since the magnetic reversal is to be completed suddenly, the core is magnetized in the direction of its magnetic preferential direction. This preferential direction is normally established during the deposition.

For the implementation of a magnetic sensor in at least two directions on a chip, two depositions having a structuring step in each case are necessary to define the magnetic alignment in the measuring direction. The magnetic reversal is influenced by the geometry of the side walls of the particular ferromagnetic core. If the particular side wall of the ferromagnetic core is not perfectly formed due to technical restrictions, this influences the magnetic reversal.

As shown in the schematic diagram of a magnetic field sensor 1 according to one specific embodiment of the present invention in FIG. 1, a substrate 2 is provided. Substrate 2 has a semiconductor substrate, for example, a silicon substrate. In principle, substrate 2 may also additionally or alternatively be a circuit board, a glass, or a ceramic, etc.

As shown in the exemplary embodiment in FIG. 1, two magnetic sensor cores 3 and 4, which measure perpendicularly or at an angle of γ=90° to one another, for example, are provided on substrate 2. First magnetic sensor core 3 is used to detect a first component of a magnetic field in a first measuring or spatial direction, the X direction here, and second magnetic sensor core 4 is used to detect a second component of the magnetic field in a second measuring or spatial direction, the Y direction here.

The deposition of the two sensor cores 3 and 4, for example, perpendicularly or at angle γ=90° to one another, is preferably performed in one deposition and only one structuring step. Each of the two magnetic sensor cores 3, 4 has a magnetic preferential direction 5, 6. Preferential direction 5 of first magnetic sensor core 3 has an angle α to measuring direction 7 of first sensor core 4, the X direction here. Preferential direction 6 of second magnetic sensor core 5 in turn has an angle β to measuring direction 8 of second sensor core 4, the Y direction here. According to an example embodiment of the present invention, the two sensor cores 3 and 4 have a shared anisotropy or anisotropy direction, as shown using an arrow 15 in the exemplary embodiment in FIG. 1.

Magnetic preferential directions 5, 6 of the two magnetic sensor cores 3, 4 are identical in the exemplary embodiment in FIG. 1 and extend at an angle α=β=45° to respective measuring direction 7, 8 of assigned sensor core 3, 4, as shown in the exemplary embodiment in FIG. 1.

Because the two magnetic sensor cores 3, 4 have the same magnetic anisotropy 15 or a magnetic preferential direction of α=β=45°, the two sensor cores 3, 4 having one anisotropy may be manufactured in only one deposition and only one structuring step, for example. The manufacturing process may thus be simplified, since substrate 2 does not have to be repositioned or rotated in each case to provide a magnetic anisotropy 15 of, for example, 45° for each of magnetic sensor cores 3, 4, but rather substrate 2 may be formed simultaneously in one position having the desired anisotropy for both sensor cores 3, 4. For example, an entire wafer or entire substrate 2 is coated using metal. Subsequently, structured lacquer is applied and the metal is removed except on sensor core 3, for example. A separating layer is subsequently applied and entire wafer or entire substrate 2 is coated using metal. Structured lacquer is then applied and the metal is removed except on sensor core 4 or the Y cores. The manufacturing costs may thus be reduced accordingly.

Furthermore, in the case of a shared magnetic anisotropy 15 of both sensor cores 3, 4 of 45°, the magnetization of particular magnetic sensor core 3, 4 takes place in each case from the center of sensor core 3 or 4 to the outside, as indicated using a double arrow in the exemplary embodiment in FIG. 1, and not as previously from side walls 9 of sensor core 3 or 4 to the inside. As a result, if one side wall 9 of magnetic sensor core 3 or 4 is not perfectly formed, it influences the magnetic reversal little or not at all.

Instead of an angle γ=90°, the two magnetic sensor cores 3 and 4 may also measure at an angle γ>90° or γ<90° to one another. Angle γ may fundamentally be in a range of 0°<γ<180°.

Shared anisotropy or shared anisotropy direction 15 in the exemplary embodiment in FIG. 1 is α=45° in relation to measuring direction 7 (X direction here) of first sensor core 3 and β=45° in relation to measuring direction 8 (Y direction here) of second sensor core 4. Shared anisotropy or shared anisotropy direction 15 may, according to the present invention, be in a range of α=20° to α=70° or accordingly β=20° to β=70° in relation to the measuring direction of one of sensor cores 3 or 4. A shared anisotropy 15 in relation to a measuring direction of one of the two sensor cores 3 or 4 in a range of α=20° to α=70° or accordingly β=20° to β=70° has the advantage that a sudden magnetic reversal of the sensor cores takes place.

Particular magnetic sensor core 3 or 4 has at least one coil, or, as shown in the exemplary embodiment in FIG. 1, a first coil 10 and a second coil 11. Both coils 10, 11 are indicated using a dashed line in FIG. 1 and may each have one or multiple winding(s). Each of the windings of particular coil 10 or 11 may be formed on substrate 2 of magnetic field sensor 1. The windings of particular first or second coil 10, 11 may enclose associated magnetic sensor core 3, 4 (not shown) or may be situated adjacent to magnetic sensor core 3, 4 or extend as illustrated in the exemplary embodiment in FIG. 1 for first and second magnetic sensor cores 3, 4.

For example, a periodic voltage shape is applied to first coil 10, for example, a delta voltage, so that a magnetic field which periodically decreases and increases is generated in the area of magnetic sensor core 3, 4. First and second magnetic sensor cores 3, 4 preferably are made in this case of a soft-magnetic material having a low or a preferably low hysteresis. Due to the magnetic alternating field which is induced by first coil 10, the magnetization of assigned magnetic sensor core 3, 4 is periodically reversed when a direction of the magnetization of magnetic sensor core 3, 4 changes. An indication of the magnetic field in magnetic sensor core 3, 4 may be determined by second coil 11, for example, a magnetic flux, a magnetic flux density, etc.

Instead of two magnetic sensor cores 3, 4, as shown in the exemplary embodiment in FIG. 1, only one magnetic sensor core 3 or 4 having at least one coil may also be provided. Furthermore, in another specific embodiment of the present invention, in addition to the two magnetic sensor cores 3, 4, a third magnetic sensor core having at least one coil may also be provided, the third magnetic sensor core measuring a third spatial direction, the Z direction here, which extends perpendicularly to substrate 2 in the exemplary embodiment shown in FIG. 1. For example, a Hall sensor may also be provided as the third magnetic sensor core for measuring the Z direction. Furthermore, a particular magnetic sensor core 3, 4 may also have only one coil instead of the above-described two coils to determine a magnetic reversal of the sensor core.

In the event of a suitable geometry of magnetic sensor cores 3, 4, a desired sudden magnetic reversal takes place in spite of rotated magnetic preferential direction 5, 6. In particular, noise of magnetic field sensor 1 having magnetic sensor cores 3, 4 may be prevented or at least reduced.

A magnetic sensor core 3, 4 having a suitable geometry has, for example, the shape of a rectangle, as shown in the exemplary embodiment in FIG. 1, or an essentially rectangular shape, a ratio between length and width of the rectangle being selected in such a way, for example, that the magnetic reversal is suddenly completed. Alternatively or additionally, the ends of the rectangle may be rounded (not shown).

Magnetic sensor cores 3, 4, as they are described on the basis of an exemplary embodiment in FIG. 1, are suitable in particular for the purpose of detecting an Earth's magnetic field or a component of an Earth's magnetic field, measuring weak magnetic fields or components of magnetic fields, etc. Such magnetic sensor cores 3, 4 may be used, for example, as magnetic field sensors or part of a magnetic field sensor, for example, in mobile telephones, navigation devices, vehicles, etc. Furthermore, an array may be formed from above-described magnetic sensor cores 3, 4, as shown in the following exemplary embodiment 3, with the aid of which, for example, components, such as cast parts or other metal parts, etc., may be examined for flaws, cracks, bubbles, etc. Such an array may be constructed from multiple magnetic sensor cores, the magnetic sensor cores measuring in the X direction, in the Y direction, and/or in the Z direction.

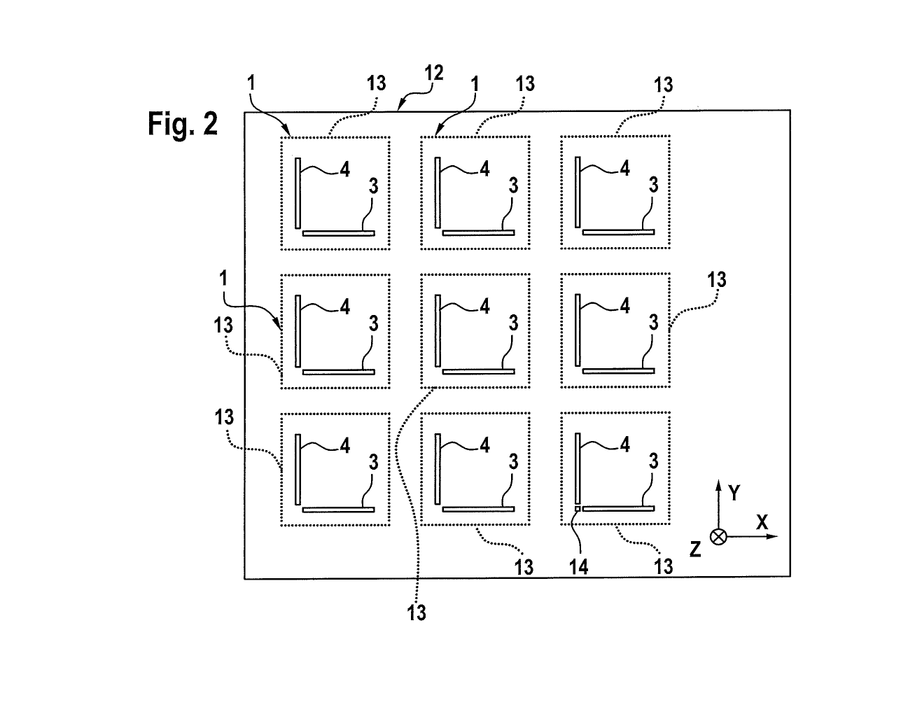

In FIG. 2, an array 12 is formed from multiple magnetic field sensors 1 according to FIG. 1. Array 12 is shown solely schematically and in greatly simplified form.

Array 12 has a substrate 2, on which multiple groups 13 of magnetic sensor cores 3, 4, 14 are provided. Groups 13 are each indicated using a dotted line in FIG. 2. In the exemplary embodiment of an array 12 shown in FIG. 2, each group 13 has, for example, two magnetic sensor cores 3 and 4. The two magnetic sensor cores 3, 4 of a group 13 correspond, for example, to sensor cores 3, 4 shown in FIG. 1.

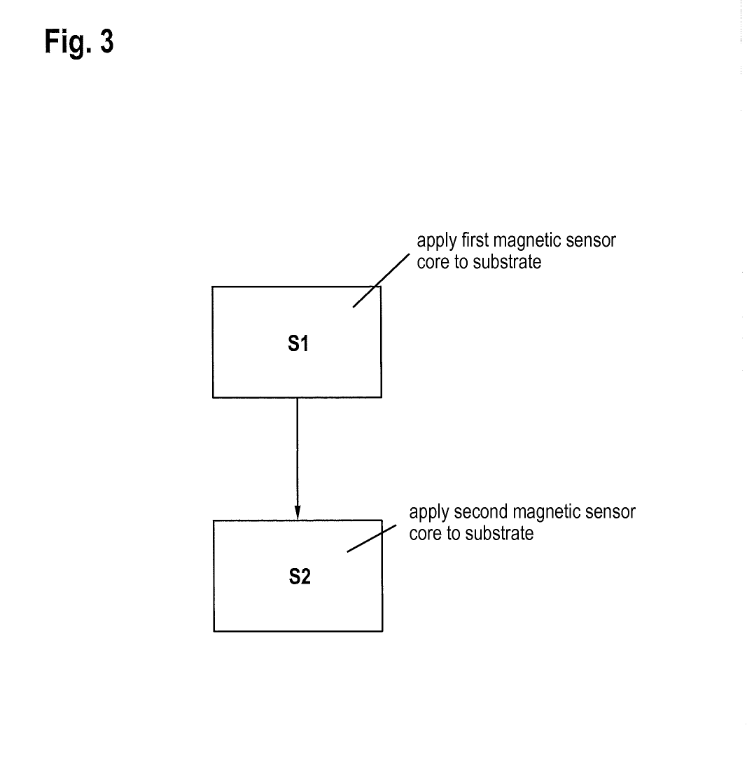

Magnetic sensor cores 3, 4 have a shared magnetic anisotropy of, for example, 45° to the measuring direction of a sensor core (not shown in FIG. 2), particular first magnetic sensor core 3 measuring in a first spatial direction, for example, the X direction and second magnetic sensor core 4 measuring in a second spatial direction, for example, the Y direction. Each sensor core 3, 4, 14 of a group 13 also has at least one coil, the coil not being shown for reasons of clarity in FIG. 3.

Groups 13 of array 12 may also have, in addition to two magnetic sensor cores 3, 4, respectively only one magnetic sensor core (not shown) or, for example, three sensor cores 3, 4, 14 (see the last group in FIG. 2), for measuring all three spatial directions. Furthermore, instead of a magnetic sensor core 14, a Hall sensor may also be provided, for example, for measuring the direction or the Z direction perpendicular to substrate 2, such as third magnetic sensor core 14 in last group 13 in the exemplary embodiment in FIG. 3. Groups 13 may each have the same configuration and/or the same number of magnetic sensor cores or at least one group may have a different configuration, e.g., positioning, magnetic anisotropy, number of coils, etc., and/or a different number of magnetic sensor cores and Hall sensors.

FIG. 3 shows an exemplary embodiment of a flow chart for the manufacture of a magnetic field sensor according to FIG. 1.

In a first step S1, a substrate is provided, for example, a semiconductor substrate or wafer, and a first magnetic sensor core having a predetermined magnetic anisotropy α is applied to the semiconductor substrate. For example, the substrate is provided with a first magnetic sensor core having a magnetic anisotropy at an angle α=45° to the measuring direction of the sensor core, for example, the X direction.

In a further step S2, a second magnetic sensor core having a predetermined magnetic anisotropy β is applied to the substrate, i.e., the semiconductor substrate. The magnetic anisotropy of the two sensor cores is selected according to the present invention in such a way that the two sensor cores have a shared anisotropy or anisotropy direction. For example, the substrate is provided with a second magnetic sensor core having a magnetic anisotropy at angle α=45° to the measuring direction of the sensor core, for example, the Y direction. The measuring directions, the X and Y directions here, of the two sensor cores are perpendicular to one another or have an angle of γ=90° in this case, for example.

The magnetic sensor cores are additionally formed by each having at least one coil.

The areas of the magnetic sensor cores may be structured out in the substrate. The structuring may take place by etching or include at least one etching step, for example. The areas of the substrate surface which are not to be etched may also be covered with the aid of photoresists and/or hard masks, for example.

Subsequently, the particular magnetic sensor core is applied to the substrate surface, for example, by depositing a soft magnetic material. The deposition may take place, for example, by chemical vapor deposition, sputtering, vaporization, or physical vapor deposition, etc. However, the present invention is not restricted to the mentioned methods for forming a magnetic sensor core having at least one coil. In principle, any method which is suitable for forming a magnetic sensor core having one coil on a substrate may be used.

Instead of the deposition of a magnetic sensor core and/or a coil of the sensor core, at least one of the magnetic sensor cores may also be manufactured as a micromechanical component and may subsequently be fastened on the surface of the substrate, for example, by gluing, welding, and/or bonding.

Although the present invention was described above in its entirety on the basis of preferred exemplary embodiments, it is not restricted thereto, but rather is modifiable in manifold ways.

Furthermore, only one magnetic sensor core having at least one coil may be provided to generate and determine a preferably sudden magnetic reversal. For example, three magnetic sensor cores may also be provided for measuring all three spatial directions, a Hall sensor optionally being able to be provided instead of at least one of the magnetic sensor cores.

What is claimed is:

1. A magnetic field sensor, comprising:
a first magnetic sensor core to measure a magnetic field in a first measuring direction; and
a second magnetic sensor core to measure a magnetic field in a second measuring direction;
wherein the first magnetic sensor core and the second magnetic sensor core have a shared magnetic anisotropy.

2. The magnetic field sensor as recited in claim 1, wherein an angle of the shared magnetic anisotropy of the first magnetic sensor core and the second magnetic sensor core is in a range of 20° to 70° to a measuring direction of one of the first sensor magnetic core or the second sensor magnetic core.

3. The magnetic field sensor as recited in claim 1, wherein the angle of the shared magnetic anisotropy is 45° to the measuring direction of the one of the first magnetic sensor core or the second magnetic sensor core.

4. The magnetic field sensor as recited in claim 1, wherein at least one of the first magnetic sensor core and the second magnetic sensor core has at least one coil to determine a magnetic reversal of the magnetic sensor core, a periodic voltage being able to be applied to the coil.

5. The magnetic field sensor as recited in claim 1, further comprising:
a third magnetic sensor core to measure a magnetic field in a third measuring direction.

6. The magnetic field sensor as recited in claim 1, further comprising:
a Hall sensor to measure a magnetic field in a third measuring direction.

7. The magnetic field sensor as recited in claim 1, wherein the angle of the measuring direction of the first magnetic sensor core to the measuring direction of the second magnetic sensor core is in a range between 0°<γ<180°.

8. The magnetic field sensor as recited in claim 1, wherein an angle of the measuring direction of the first magnetic sensor core to the measuring direction of the second magnetic sensor core is 90°.

9. An array, comprising:
a plurality of magnetic field sensors, each of the magnetic field sensors including a first magnetic sensor core to measure a magnetic field in a first measuring direction, and a second magnetic sensor core to measure a magnetic field in a second measuring direction, wherein the first magnetic sensor core and the second magnetic sensor core have a shared magnetic anisotropy.

10. A component having at least one magnetic field sensor, the magnetic field sensor including a plurality of magnetic field sensors, each of the magnetic field sensors including a first magnetic sensor core to measure a magnetic field in a first measuring direction, and a second magnetic sensor core to measure a magnetic field in a second measuring direction, wherein the first magnetic sensor core and the second magnetic sensor core have a shared magnetic anisotropy.

11. The component as recited in claim 10, wherein the component is at least one of a mobile telephone, a PC, a Tablet PC, a notebook, and a navigation device.

12. A method for manufacturing a magnetic field sensor, comprising:
applying a first magnetic sensor core to a substrate having an anisotropy at a predetermined angle to a measuring direction of the first magnetic sensor core; and
applying a second magnetic sensor core to the substrate having an anisotropy at a predetermined angle to a measuring direction of the second magnetic sensor core, an angle of the anisotropy to the measuring direction of the sensor cores being selected in such a way that the first magnetic sensor core and the second magnetic sensor core have a shared anisotropy.

13. The method as recited in claim 12, wherein the step of applying the magnetic anisotropy includes applying the shared magnetic anisotropy of the first magnetic sensor core and the second magnetic sensor core at an angle in a range of 20° to 70° to the measuring direction of one of the sensor cores, the application of the magnetic anisotropy taking place by sputtering.

14. The method as recited in claim 13, wherein the angle is 45°.

15. The method as recited in claim 12, wherein the steps of applying a first magnetic sensor core and the second magnetic sensor core to the substrate includes:
applying the first magnetic sensor core and the second magnetic sensor core having their particular measuring direction at an angle to one another on the substrate, the angle being in a range between 0°<γ<180°, and the application of each magnetic sensor core to the substrate taking place by depositing a soft magnetic material.
